(19) United States
(12) Patent Application Publication
(10) Pub. No.: US 2026/0222087 A1
(43) Pub. Date: Jul. 30, 2026

(54) DEVICE FOR CONTROLLING IMPEDANCE OF ANTENNA TUNER, COMMUNICATION DEVICE INCLUDING THE SAME, AND METHOD OF OPERATION THEREOF

(71) Applicant: Samsung Electronics Co., Ltd., Suwon-si (KR)

(72) Inventors: Sunah PARK, Suwon-si (KR); Ohseok KIM, Suwon-si (KR)

(73) Assignee: Samsung Electronics Co., Ltd., Suwon-si (KR)

(21) Appl. No.: 19/416,592

(22) Filed: Dec. 11, 2025

(30) Foreign Application Priority Data
Jan. 24, 2025 (KR) 10-2025-0010902

(51) Int. Cl. H04B 17/11; H01Q 5/335; H04B 17/21

(52) U.S. Cl. CPC H04B 17/11; H01Q 5/335; H04B 17/21

(57) ABSTRACT

A communication device includes a first tuning network including a first antenna and a first antenna tuner configured to adjust an impedance according to a received tune code, a first processor configured to identify a first reflection coefficient based on a first forward signal and a first reverse signal, the first forward signal being transmitted to the first antenna through the first antenna tuner, the first reverse signal being received through the first antenna tuner as at least a portion of the first forward signal is reflected, and a second processor configured to execute a machine learning model trained based on a plurality of training reflection coefficients and a plurality of training events, the first processor being configured to provide the first reflection coefficient to the second processor, and identify a first event corresponding to the first reflection coefficient based on an output of the machine learning model provided.

### CROSS-REFERENCE TO RELATED APPLICATIONS

This application claims the benefit of Korean Patent Application No. 10-2025-0010902, filed on Jan. 24, 2025, in the Korean Intellectual Property Office, the disclosure of which is incorporated herein by reference in its entirety.

### BACKGROUND

### 1. Technical Field

Example embodiments relate to wireless communications, and more particularly, to a device for controlling impedance of an antenna tuner, a communication device including the same, and a method of operation thereof.

### 2. Description of the Related Art

In order to reduce reflection loss of an antenna, which may be used in a wireless communication system, impedance may be dynamically adjusted using an antenna tuner. For a mobile device such as a smartphone and a tablet, a grip sensor may be used to compensate for an electrical change generated when a user grips the device. However, the grip sensor may increase the cost and complexity of the mobile device.

### SUMMARY

Aspects of the present disclosure provide a device for detecting various events based on a reflection coefficient of an antenna and controlling impedance of an antenna tuner based on a detected event, a communication device including the same, and a method of operation thereof.

According to example embodiments, there is provided a communication device including a first tuning network including a first antenna and a first antenna tuner, the first antenna tuner being configured to adjust a first impedance according to a first received tune code, a first processor configured to identify a first reflection coefficient based on a first forward signal and a first reverse signal, the first forward signal being transmitted to the first antenna through the first antenna tuner, and the first reverse signal being received through the first antenna tuner as at least a portion of the first forward signal is reflected, and a second processor configured to execute a machine learning model, the machine learning model being trained based on a plurality of training reflection coefficients and a plurality of training events, the first processor is configured to provide the first reflection coefficient to the second processor, and identify a first event corresponding to the first reflection coefficient based on an output of the machine learning model provided from the second processor.

According to example embodiments, there is provided a method of controlling impedance of at least one antenna tuner, the method including identifying a first reflection coefficient based on a first forward signal and a first reverse signal, the first forward signal being transmitted to a first antenna through a first antenna tuner, and the first reverse signal being received through the first antenna tuner as at least a portion of the first forward signal is reflected, providing the first reflection coefficient to a machine learning model trained based on a plurality of training reflection coefficients and a plurality of training events, and identifying a first event corresponding to the first reflection coefficient based on an output of the machine learning model.

According to example embodiments, there is provided a device configured to control an impedance of at least one antenna tuner, the device including processing circuitry configured to identify a reflection coefficient based on a forward signal and a reverse signal, the forward signal being transmitted to a first antenna through a first antenna tuner, and the reverse signal received through the first antenna tuner as at least a portion of the forward signal is reflected, provide the reflection coefficient to a machine learning model trained based on a plurality of training reflection coefficients and a plurality of training events, and identify an event corresponding to the reflection coefficient based on an output of the machine learning model.

According to example embodiments, there is provided a non-transitory computer-readable medium storing instructions that, when executed by processing circuitry of a communication device, cause the communication device to perform a method, the method including identifying a first reflection coefficient based on a first forward signal and a first reverse signal, the first forward signal being transmitted to a first antenna through a first antenna tuner, and the first reverse signal being received through the first antenna tuner as at least a portion of the first forward signal is reflected, providing the first reflection coefficient to a machine learning model trained based on a plurality of training reflection coefficients and a plurality of training events, and identifying a first event corresponding to the first reflection coefficient based on an output of the machine learning model.

According to example embodiments, by a device, a communication device including the same, and a method of operation thereof, it is possible to detect various events through an antenna and control impedance of an antenna tuner based on a detected event.

According to example embodiments, it is possible to detect various events through a feedback tuning network without dedicated sensors for sensing a specific event. According to example embodiments, it is possible to achieve a cost reduction and a simplification of hardware design due to omitted dedicated sensors and simultaneously improve communication performance.

Effects of example embodiments are not limited to those described above, and other unstated effects may be clearly inferred and understood by those skilled in the art to which example embodiments pertain from the following description. In other words, unintended effects to be obtained by implementing example embodiments may also be inferred by those skilled in the art from example embodiments.

### BRIEF DESCRIPTION OF THE FIGURES

These and/or other aspects, features, and advantages of the inventive concepts will become apparent and more readily appreciated from the following description of example embodiments, taken in conjunction with the accompanying drawings of which:

FIG. 1 is a block diagram illustrating a communication device according to example embodiments of the present disclosure;

FIG. 2 is a diagram for illustrating a tuning network according to example embodiments of the present disclosure;

FIG. 3 is a flowchart for illustrating a method of controlling impedance of an antenna tuner according to example embodiments of the present disclosure;

FIG. 4 is a diagram for illustrating a reflection coefficient and an event according to example embodiments of the present disclosure;

FIG. 5 is a diagram for illustrating a second processor according to example embodiments of the present disclosure;

FIG. 6 is a diagram for illustrating a trained machine learning model according to example embodiments of the present disclosure;

FIG. 7 is a flowchart for illustrating a method of controlling impedance of an antenna tuner according to example embodiments of the present disclosure;

FIG. 8 is a flowchart for illustrating a method of controlling impedance of an antenna tuner according to example embodiments of the present disclosure;

FIG. 9 is a flowchart for illustrating a method of controlling impedance of an antenna tuner according to example embodiments of the present disclosure; and

FIG. 10 is a block diagram illustrating an example of a device according to example embodiments of the present disclosure.

### DETAILED DESCRIPTION

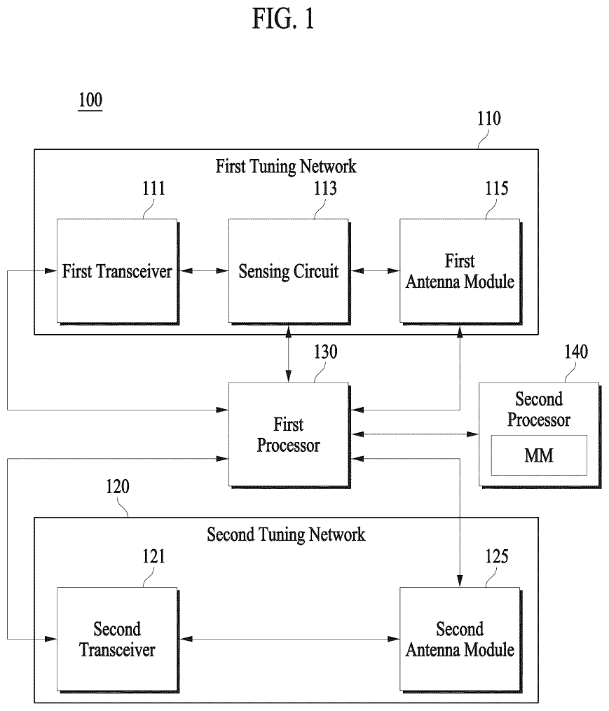

FIG. 1 is a block diagram illustrating a communication device 100 according to example embodiments of the present disclosure. The communication device 100 may be any device that may communicate with another communication device. For example, the communication device 100 may be included in a mobile device such as a laptop personal computer (PC), a smartphone, a tablet PC, etc., and/or may be included in a stationary device such as a desktop PC, a server, an access point (AP), etc.

Referring to FIG. 1, the communication device 100 may include a first tuning network 110, a second tuning network 120, a first processor 130, and/or a second processor 140. In example embodiments, the communication device 100 may further include an additional first tuning network. In example embodiments, the communication device 100 may further include an additional second tuning network. In example embodiments, the second tuning network 120 may be omitted from the communication device 100.

The communication device 100 may communicate with another communication device, for example, an external device, through the first tuning network 110 and/or the second tuning network 120. For example, the communication device 100 may be implemented in various forms such as a semiconductor chip for communication, a network interface card (NIC), a smartphone, a tablet PC, a wearable device, a connected car, a communications satellite, a mobile communication base station, etc. In example embodiments, the communication device 100 may transmit and receive signals using a cellular network such as a 5th generation (5G), a long term evolution (LTE), an LTE-advanced, a code division multiple access (CDMA), a global system for mobile communications (GSM), etc. In example embodiments, the communication device 100 may transmit and receive signals using a communication manner such as Bluetooth, near field communication (NFC), wireless fidelity (Wi-Fi), Zigbee, wireless local area network (WLAN), vehicle to everything (V2X), satellite communication, etc. The above-described examples are merely examples, and the communication device 100 may transmit and receive signals using various wireless communication manners.

In example embodiments, the first tuning network 110 may operate in a closed-loop antenna impedance tuning (CL-AIT) manner. For example, the CL-AIT manner may refer to a manner of monitoring an impedance state of a first antenna module 115 in real time using a feedback loop and dynamically adjusting impedance of the first antenna module 115 based on monitored data. In example embodiments, the second tuning network 120 may operate in an open-loop antenna impedance tuning (OL-AIT) manner. The OL-AIT manner may refer to a manner of adjusting impedance based on a lookup table defined in advance and may not use a feedback loop unlike the CL-AIT manner. In example embodiments, the first processor 130 may select at least one of the first tuning network 110 and/or the second tuning network 120 to transmit a signal through the selected tuning network.

The first tuning network 110 may include a first transceiver 111, a sensing circuit 113, and/or the first antenna module 115. The second tuning network 120 may include a second transceiver 121 and/or a second antenna module 125.

The first transceiver 111 may be connected to the first antenna module 115 through the sensing circuit 113. The first transceiver 111 may process a signal between the first antenna module 115 and the first processor 130. For example, the first transceiver 111 may convert a baseband signal provided from the first processor 130 into a radio frequency (RF) signal and transmit the RF signal to the first antenna module 115. The first transceiver 111 may convert an RF signal received through the first antenna module 115 into a baseband signal and transmit the baseband signal to the first processor 130.

The sensing circuit 113 may be a circuit for measuring a reflection coefficient. For example, the sensing circuit 113 may detect a forward signal (or a corresponding signal) and/or a reverse signal (or a corresponding signal). The forward signal may be a signal transmitted from the first transceiver 111 to the first antenna module 115 and a signal proceeding in a forward direction. The forward direction may be a direction proceeding along a transmission path leading from the first transceiver 111 to the first antenna module 115. The reverse signal may be a signal reflected from the first antenna module 115 and a signal proceeding in a reverse direction. The reverse direction may be an opposite direction of the forward direction. The sensing circuit 113 may provide a detected signal (or corresponding data) to the first processor 130.

The first antenna module 115 may transmit an RF signal provided from the first transceiver 111 to an external device or transmit an RF signal received from the external device to the first transceiver 111. The first antenna module 115 may include an antenna tuner (hereinafter referred to as a first antenna tuner) of which impedance is adjusted according to a tune code (may also be referred to herein as a received tune code) provided from the first processor 130 for impedance matching.

The second transceiver 121 may be connected to the second antenna module 125. The second transceiver 121 may process a signal between the second antenna module 125 and the first processor 130. For example, the second transceiver 121 may convert a baseband signal provided from the first processor 130 into an RF signal and transmit the RF signal to the second antenna module 125, and/or may convert an RF signal received through the second antenna module 125 into a baseband signal and transmit the baseband signal to the first processor 130.

The second antenna module 125 may transmit an RF signal provided from the second transceiver 121 to an external device or transmit an RF signal received from the external device to the second transceiver 121. The second antenna module 125 may include an antenna tuner (hereinafter referred to as a second antenna tuner) of which impedance is adjusted according to a tune code (may also be referred to herein as a received tune code) provided from the first processor 130 for impedance matching.

The first processor 130 may perform an operation corresponding to at least one layer of a defined wireless protocol structure in a wireless communication system including the communication device 100. In addition, the first processor 130 may control impedance of at least one antenna tuner. For example, the first processor 130 may control impedance of the first antenna tuner included in the first antenna module 115. The first processor 130 may control impedance of the second antenna tuner included in the second antenna module 125. In example embodiments, the first processor 130 may be implemented as hardware designed by logic synthesis, a processing unit including a core and software executed by the core, or a combination thereof. In example embodiments, the first processor 130 may include or access a memory for storing data used for operations or processing. In example embodiments, the first processor 130 may be referred to as a communication processor or a modem.

The first processor 130 may identify (or detect) a reflection coefficient through the first tuning network 110. The first processor 130 may provide the reflection coefficient to the second processor 140. The reflection coefficient may be a coefficient quantitatively indicating reflection occurring in the transmission path between the first transceiver 111 and the first antenna module 115 and may indicate a matching state (or matching degree) of impedance. The reflection coefficient may indicate that, if the matching state of impedance is not optimized (or improved), a signal transmission efficiency may be reduced and a signal loss may be caused. As illustrated in FIG. 1, the second processor 140 may include a machine learning model MM, and the first processor 130 may identify an event corresponding to the reflection coefficient based on an output of the machine learning model MM provided from the second processor 140. For example, the first processor 130 may receive the output of the machine learning model MM from the second processor 140. The first processor 130 may identify the event corresponding to the reflection coefficient based on the output of the machine learning model MM. The event may be predefined (or alternatively, given or defined) as various states (for example, a physical state and an environmental state) influencing the reflection coefficient. In example embodiments, the first processor 130 may dynamically adjust impedance of the first antenna module 115 and/or the second antenna module 125 based on the identified event.

The second processor 140 may execute the machine learning model MM. The machine learning model MM may be in a state trained based on a plurality of reflection coefficients (e.g., a plurality of training reflection coefficients) and a plurality of events (e.g., a plurality of training events). The second processor 140 may provide the first processor 130 with the output (or output data) generated by the machine learning model MM in response to the reflection coefficient provided from the first processor 130. According to example embodiments, the machine learning model MM may generate the output (or output data) in response to input of the reflection coefficient to the machine learning model MM (or in response to application of the machine learning model MM to the reflection coefficient). The machine learning model MM may be any model trained by a plurality of reflection coefficients and a plurality of events. In example embodiments, the second processor 140 may include hardware designed to execute the machine learning model MM and may include a memory for storing data used to execute the machine learning model MM. In example embodiments, the first processor 130 and the second processor 140 may be implemented as separate processors from each other. In example embodiments, the first processor 130 and the second processor 140 may be implemented in the form of a single integrated chip. In this case, operations of the first processor 130 and the second processor 140 may be performed by a single processor.

In example embodiments, the communication device 100 may further include a memory. The memory may store a variety of data. In example embodiments, the memory may include non-volatile memory such as NAND flash memory and resistive memory. In example embodiments, the memory may include volatile memory such as static random access memory (SRAM) and dynamic random access memory (DRAM). The first processor 130 and/or the second processor 140 may access data stored in the memory.

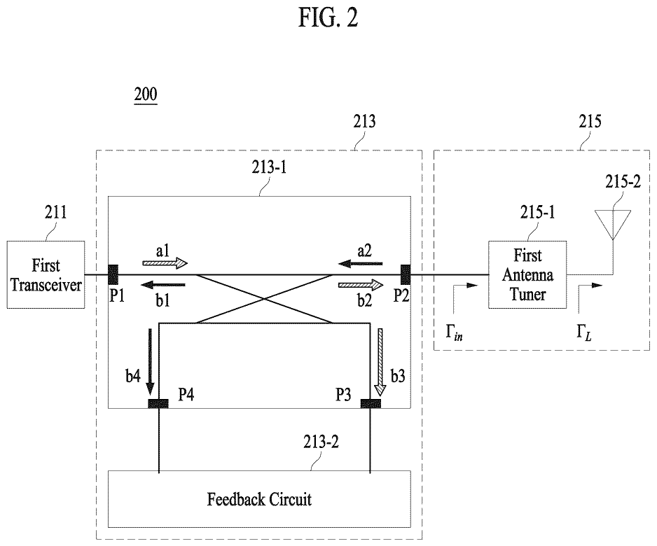

FIG. 2 is a diagram for illustrating a first tuning network according to example embodiments of the present disclosure. In example embodiments, a first tuning network 200 of FIG. 2 may be an example of the first tuning network 110 of FIG. 1.

Referring to FIG. 2, the first tuning network 200 may include a first transceiver 211, a sensing circuit 213, and/or a first antenna module 215. Referring to FIGS. 1 and 2, the first tuning network 200 may be connected to the first processor 130 of FIG. 1. The sensing circuit 213 may include a coupler 213-1 and a feedback circuit 213-2. The first antenna module 215 may include a first antenna tuner 215-1 and a first antenna 215-2. According to example embodiments, the first transceiver 211 may be an example of the first transceiver 111 of FIG. 1, the sensing circuit 213 may be an example of the sensing circuit 113 of FIG. 1, and the first antenna module 215 may be an example of the first antenna module 115 of FIG. 1.

The first transceiver 211 may be connected to the coupler 213-1 and the first processor 130. The first transceiver 211 may include a transmitter, a receiver, and/or a switch. The transmitter may generate an RF signal by converting a baseband signal provided from the first processor 130 and transmit the generated RF signal to the first antenna 215-2 through the coupler 213-1 and the first antenna tuner 215-1. In example embodiments, the transmitter may include a filter, a mixer, and/or a power amplifier. The receiver may receive an RF signal received by the first antenna 215-2 through the first antenna tuner 215-1 and the coupler 213-1, generate a baseband signal by converting the received RF signal, and transmit the generated baseband signal to the first processor 130. In example embodiments, the receiver may include a filter, a mixer, and/or a low noise amplifier. The switch may be set in a transmission mode or a reception mode, and may dynamically convert (or switch) between the transmission mode and the reception mode. In the transmission mode, the RF signal generated in the transmitter may be transmitted to the first antenna 215-2 through the coupler 213-1 and the first antenna tuner 215-1, and in the reception mode, the RF signal received by the first antenna 215-2 may be transmitted to the receiver through the first antenna tuner 215-1 and the coupler 213-1. In example embodiments, the switch may include a duplexer and/or a switchplexer or may be replaced therewith. In example embodiments, the first transceiver 211 may be referred to as a radio frequency integrated circuit (RFIC).

The coupler 213-1 may be connected between the first transceiver 211 and the first antenna tuner 215-1. The coupler 213-1 may capture a feedback forward signal of a forward signal on a transmission path and a feedback reverse signal of a reverse signal. For example, the forward signal may represent an RF signal generated in the transmitter and transmitted toward the first antenna 215-2, and the reverse signal may represent an RF signal reflected and returned from the first antenna 215-2. The feedback forward signal and the feedback reverse signal may be a signal coupled to the forward signal and a signal coupled to the reverse signal, respectively. The coupler 213-1 may transmit the captured feedback forward signal and/or feedback reverse signal to the feedback circuit 213-2. In example embodiments, the coupler 213-1 may set a coupling direction as a forward coupling direction or a reverse coupling direction. When the forward coupling direction is set, the coupler 213-1 may capture the feedback forward signal from the forward signal. When the reverse coupling direction is set, the coupler 213-1 may capture the feedback reverse signal from the reverse signal. In example embodiments, the coupling direction of the coupler 213-1 may be set according to a coupler control signal provided from the first processor 130. In example embodiments, the coupler 213-1 may be referred to as a bidirectional coupler. The coupler 213-1 may provide information on the feedback forward signal and the feedback reverse signal to the first processor 130 through the feedback circuit 213-2.

In example embodiments, the coupler 213-1 may include an input port P1, an output port P2, a first feedback port P3, and/or a second feedback port P4. A first forward signal a1 transmitted from the first transceiver 211 may be transmitted inside the coupler 213-1 through the input port P1. A second forward signal b2, which is at least a portion of the first forward signal a1, may be transmitted to the first antenna tuner 215-1 through the output port P2. A first signal b3 may be transmitted to the feedback circuit 213-2 through the first feedback port P3. The first signal b3 may be a feedback forward signal obtained by sampling at least a portion of the first forward signal a1. A first reverse signal a2 reflected from the first antenna 215-2 may be transmitted inside the coupler 213-1 through the output port P2. A second reverse signal b1, which is at least a portion of the first reverse signal a2, may be transmitted to the first transceiver 211 through the input port P1. A second signal b4 may be transmitted to the feedback circuit 213-2 through the second feedback port P4. The second signal b4 may be a feedback reverse signal obtained by sampling a portion of the first reverse signal a2.

The feedback circuit 213-2 may be connected to the coupler 213-1 and the first processor 130. The feedback circuit 213-2 may receive a feedback signal (for example, a feedback forward signal and/or a feedback reverse signal) provided from the coupler 213-1. The feedback circuit 213-2 may analyze the feedback signal to generate feedback data for monitoring a reflection characteristic on a transmission path in real time and provide the feedback data to the first processor 130. The feedback data may include characteristic information of each of the feedback forward signal and/or the feedback reverse signal. For example, the characteristic information may include an amplitude and a phase. As another example, the characteristic information may include information on an in-phase (I) component and a quadrature-phase (Q) component used to calculate an amplitude and a phase. The first processor 130 may identify a reflection coefficient based on the feedback data. In example embodiments, the feedback circuit 213-2 may include a filter that removes an unnecessary frequency component or a noise, and a mixer. The feedback circuit 213-2 may include an analog-to-digital (A/D) converter that converts the feedback signal to a digital signal. The feedback circuit 213-2 may extract an I component and a Q component for each of the feedback forward signal and the feedback reverse signal in the process of digitizing each of the feedback forward signal and the feedback reverse signal. In example embodiments, at least a portion of the feedback circuit 213-2 may be implemented in a form integrated into the coupler 213-1 or the first processor 130.

A reflection coefficient may indicate information on a signal reflected due to an impedance mismatch with a load (for example, the first antenna 215-2) in a transmission path, for example, as a complex number including an amplitude ratio and a phase difference between a forward signal and a reverse signal. In example embodiments, the reflection coefficient of the present disclosure may include a reflection coefficient Γᵢₙ of the first antenna tuner 215-1 or a reflection coefficient Γ_{L} of the first antenna 215-2. The reflection coefficient Γᵢₙ of the first antenna tuner 215-1 may be an input reflection coefficient as seen from an input port of the first antenna tuner 215-1. The reflection coefficient Γ_{L} of the first antenna 215-2 may be a load reflection coefficient as seen from an input port of the first antenna 215-2.

In example embodiments, the first processor 130 may identify (or calculate) the reflection coefficient Γᵢₙ of the first antenna tuner 215-1 based on a forward signal and a reverse signal. In example embodiments, the first processor 130 may identify (or calculate) the reflection coefficient Γ_{L} of the first antenna 215-2 based on the reflection coefficient Γᵢₙ of the first antenna tuner 215-1 and a scattering parameter (S-parameter) set. The S-parameter set may indicate reflection and transmission characteristics of a signal. In example embodiments, the S-parameter set may include an input reflection parameter, a reverse transmission parameter, a forward transmission parameter, and/or an output reflection parameter. For example, the forward transmission parameter (for example, S₂₁) may represent a ratio (for example, b2/a1) of a signal transmitted to the output port P2 to a signal inputted through the input port P1, and the reverse transmission parameter (for example, S₁₂) may represent a ratio (for example, b1/a2) of a signal transmitted to the input port P1 to a signal inputted through the output port P2. The input reflection parameter (for example, S₁₁) may represent a ratio (for example, b1/a1) of a reflected signal to a signal inputted through the input port P1, and the output reflection parameter (for example, S₂₂) may represent a ratio (for example, b2/a2) of a reflected signal to a signal inputted through the output port P2.

The first antenna 215-2 may transmit an RF signal (for example, a forward signal) to an external device and/or receive an RF signal (for example, a received signal) from the external device. The first antenna 215-2 may have a unique (or defined) load impedance for a specific frequency band, but load impedance may vary depending on an event (for example, a contact or approach state of a user body or an object, and an external device connection). In this case, a reverse signal may be generated as a portion of a forward signal is reflected due to a mismatch between a load impedance of the first antenna 215-2 and a reference impedance (for example, 50 ohm (Ω)) of a transmission path. In example embodiments, the first processor 130 may perform impedance matching between the load impedance and the reference impedance by adjusting a variable impedance of the first antenna tuner 215-1 connected to the first antenna 215-2. In example embodiments, the first antenna 215-2 may be composed of an antenna array including a plurality of antennas, and may support multiple input multiple output (MIMO) and beam forming.

The first antenna tuner 215-1 may have the variable impedance. The first antenna tuner 215-1 may perform a role of reducing a mismatch between the first antenna 215-2 and the reference impedance of the transmission path through the variable impedance. In example embodiments, the first antenna tuner 215-1 may include at least one of an inductor, a capacitor, a transformer, a diode, a transistor, and/or an RF switch. The first antenna tuner 215-1 may further include an amplifier and/or a resistor. The impedance of the first antenna tuner 215-1 may be adjusted according to a tune code (or a control signal) provided from the first processor 130. In example embodiments, the tune code may include a set value (or a parameter value) for adjusting (or setting) the variable impedance of the first antenna tuner 215-1. Accordingly, even if the load impedance of the first antenna 215-2 is varied by a user or an environment, by compensating for the load impedance in real time, a reflection coefficient may be reduced and a transmission efficiency may be improved.

In example embodiments, the second tuning network 120 of FIG. 1 may correspond to the first tuning network 200 with the sensing circuit 213 of FIG. 2 omitted. For example, as described above with reference to FIG. 1, the second tuning network 120 may include the second transceiver 121 and the second antenna module 125. The second antenna module 125 may include the second antenna tuner, configured to adjust impedance according to a tune code provided from the first processor 130, and a second antenna. The descriptions of the first transceiver 211 and the first antenna module 215 of the first tuning network 200 may be applied to the second transceiver 121 and the second antenna module 125 of the second tuning network 120, respectively.

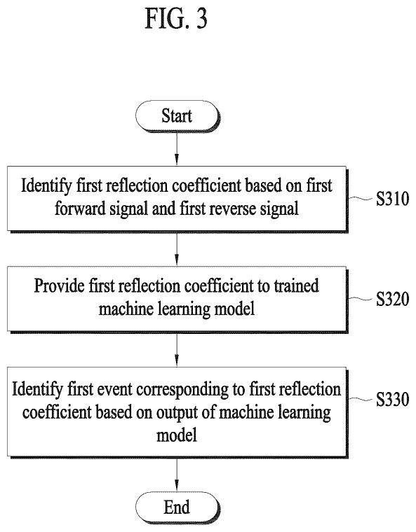

FIG. 3 is a flowchart for illustrating a method of controlling impedance of an antenna tuner according to example embodiments of the present disclosure. In example embodiments, the method of FIG. 3 may be performed by the first processor 130 of FIG. 1. Hereinafter, it is assumed that the first processor 130 of FIG. 1 controls the first antenna tuner 215-1 of FIG. 2. Referring to FIGS. 1 to 3, a method of controlling impedance of the first antenna tuner 215-1 may include a plurality of operations S310 to S330.

In operation S310, a first reflection coefficient may be identified based on a first forward signal and a first reverse signal. In example embodiments, the first processor 130 may identify the first reflection coefficient based on the first forward signal and the first reverse signal. For example, the first forward signal may be a signal transmitted to the first antenna 215-2 through the first antenna tuner 215-1 while the first antenna tuner 215-1 is at an initial impedance, and the first reverse signal may be a signal received through the first antenna tuner 215-1 as at least a portion of the first forward signal is reflected. In example embodiments, the initial impedance may be an impedance adjusted according to an initial tune code of a current frequency band or a currently set tune code. In example embodiments, the first reflection coefficient may include the reflection coefficient Γᵢₙ of the first antenna tuner 215-1 or the reflection coefficient Γ_{L} of the first antenna 215-2.

In operation S320, the first reflection coefficient may be provided to a trained machine learning model. In example embodiments, the first processor 130 may provide the first reflection coefficient to the trained machine learning model. For example, the first processor 130 may provide the first reflection coefficient to the second processor 140. As described above with reference to FIG. 1, the second processor 140 may be a device that executes the trained machine learning model. The second processor 140 may obtain an output of the machine learning model by executing the machine learning model based on the first reflection coefficient (e.g., by inputting the first reflection coefficient to the machine learning model). The second processor 140 may provide the output of the machine learning model to the first processor 130.

The trained machine learning model may be in a state trained by a plurality of reflection coefficients and a plurality of events. Specifically, the trained machine learning model may be trained to use each of the plurality of reflection coefficients as an input (or a feature vector) and obtain an event corresponding to each of the plurality of reflection coefficients as an output (or a label vector). For example, the trained machine learning model may learn a relationship (e.g., correlations) between input data and output data through various learning manners such as supervised learning and unsupervised learning. In example embodiments, the plurality of events may include at least one of a grip event, a head event, a free event, and/or a connection event. However, this is merely an example, and a type of event included in the plurality of events may be added or replaced according to a user action characteristic, an antenna arranged environment, and/or a change in a surrounding object.

In operation S330, a first event corresponding to the first reflection coefficient may be identified based on the output of the machine learning model. In example embodiments, the first processor 130 may identify the first event corresponding to the first reflection coefficient based on the output of the machine learning model corresponding to the first reflection coefficient. For example, the first processor 130 may receive the output of the machine learning model from the second processor 140 and identify the first event corresponding to the first reflection coefficient based on the output of the machine learning model. The first event may be one event corresponding to the first reflection coefficient among the plurality of events predefined (or alternatively, given or defined).

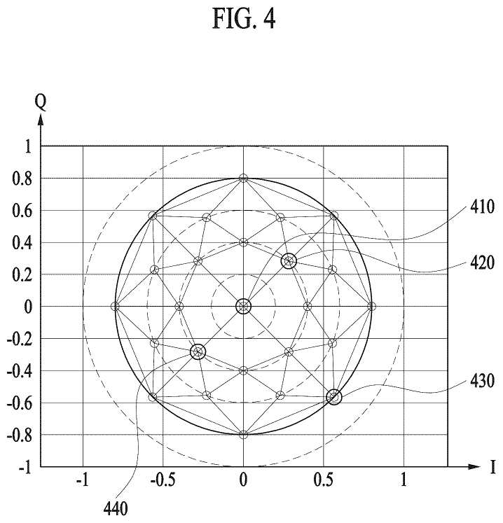

FIG. 4 is a diagram for illustrating a reflection coefficient and an event according to example embodiments of the present disclosure. FIG. 4 is an example of an I component (real part) and a Q component (imaginary part) of a normalized reflection coefficient shown in a gamma chart and visually represents data corresponding to a magnitude (or amplitude) and a phase of the reflection coefficient.

Referring to FIG. 4, a reflection coefficient may be mapped to a unique point on the gamma chart according to an I component and a Q component. A magnitude (or amplitude) of a reflection coefficient may be a distance between a point corresponding to the reflection coefficient and the center (or origin) of the chart. A phase of a reflection coefficient may be an angle between a point corresponding to the reflection coefficient and a horizontal axis passing through the center (or origin) of the chart.

In example embodiments, the first processor 130 of FIG. 1 may cluster a plurality of reflection coefficients on the gamma chart according to a plurality of events. The first processor 130 may analyze a state of the communication device 100 through clustering and use the state for antenna tuning. In example embodiments, the plurality of events may include at least one of a free event 410, a connection event 420, a head event 430, and/or a grip event 440. The free event 410 may be an event corresponding to a state in which an antenna has no interference by an external object (e.g., corresponding to an absence of interference at the antenna from the external object). The connection event 420 may be an event corresponding to a state in which an external device is connected to the communication device 100 through a cable such as a universal serial bus (USB) cable. The head event 430 may be an event corresponding to a state in which a head of a user is in contact with at least a portion of an antenna. The grip event 440 may be an event corresponding to a state in which a hand of the user is in contact with at least a portion of an antenna. For example, the free event may be an event of a state in which the first antenna 215-2 is exposed in an open space or an object that causes electromagnetic interference is not present around. For example, the connection event may be an event of a state in which an external device or external power is connected to the communication device 100 through a cable such as a USB or an earphone is physically connected to the communication device 100. For example, the head event may be an event of a state in which the user holds the communication device 100 on the ear for a call. For example, the grip event may be an event of a state in which the user holds the communication device 100 in the hand with the first antenna 215-2 surrounded. However, this is merely an example, and a type of event may be modified and implemented in various manners.

However, if a boundary between events is unclear or clusters overlap, the accuracy of an event identified through a reflection coefficient may be reduced. In addition, a subjective judgment of a user (or a developer) may be used to interpret clustering based on the gamma chart. As described above with reference to the drawings, the communication device 100 according to example embodiments of the present disclosure may accurately identify an event using a machine learning model. According to the present disclosure, due to a trained machine learning model, a clustering relationship between various events influencing reflection coefficients and the reflection coefficients may be accurately interpreted without subjective judgments.

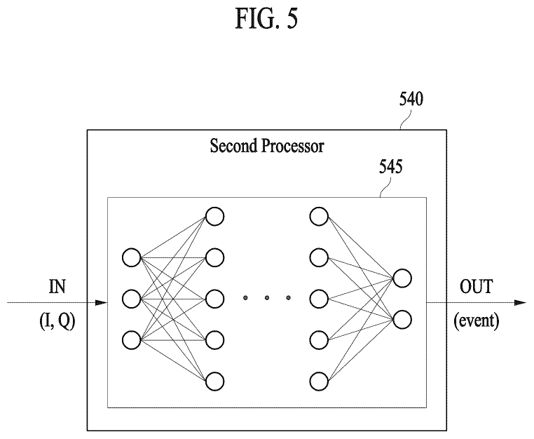

FIG. 5 is a diagram for illustrating a second processor according to example embodiments of the present disclosure.

Referring to FIG. 5, a second processor 540 may execute a machine learning model 545. According to example embodiments, the second processor 540 may be an example of the second processor 140 discussed in connection with FIG. 1. The machine learning model 545 may generate an output OUT (or output data) corresponding to an input IN (or input data) based on the input IN. The machine learning model 545 may be in a state trained in advance so that the output OUT is generated based on the input IN, and the trained state may be stored in an internal memory of the second processor 540 or an external memory.

The input IN of the machine learning model 545 may include a reflection coefficient. In example embodiments, the input IN may further include at least one of various types of data, such as temperature, humidity, a frequency band, an antenna location, and/or time, as a factor related to an event and may be implemented as multidimensional data. The output OUT of the machine learning model 545 may be a result value generated in response to the input IN, and may indicate a specific event or include information related to a specific event.

The machine learning model 545 may be any model trained by a plurality of reflection coefficients and a plurality of events. In example embodiments, the machine learning model 545 may refer to any model that may be trained by training data. For example, the machine learning model 545 may be a model based on an artificial neural network, a decision tree, a support vector machine, a regression analysis, a Bayesian network, or a genetic algorithm. Hereinafter, the machine learning model 545 is described mainly with reference to the artificial neural network, but example embodiments of the present disclosure are not limited thereto. For example, the artificial neural network may be one of various types such as a convolutional neural network (CNN) for learning a nonlinear relationship between a reflection coefficient and an event, a multi-layer perceptron (MLP), a fully connected neural network for identifying an event by analyzing data including a reflection coefficient, a recurrent neural network (RNN) for processing a reflection coefficient according to time, a region with convolution neural network (R-CNN), a region proposal network (RPN), a long short-term memory (LSTM) network, a stacking-based deep neural network (S-DNN), a state-space dynamic neural network (S-SDNN), a deconvolution network, a deep belief network (DBN), a restricted Boltzmann machine (RBM), and a classification network.

In example embodiments, the machine learning model 545 may include a plurality of layers. For example, the plurality of layers may include an input layer, one or more hidden layers, and an output layer. The input layer may be a layer that receives input data, the hidden layer may be an intermediate layer that non-linearly converts the input data to learn a feature, and the output layer may be a layer that outputs a result based on the learned feature. Each layer may include one or more neurons. Each neuron may generate an output for an input using various types of activation functions such as a rectified linear unit (ReLU), sigmoid, tanh, softmax, and/or a linear function. A weight may be applied to the neurons connected between the layers. The weight may be a value indicating a correlation between an input and a neuron and may be updated as an adjusted value to minimize (or reduce) a loss function in a training process. The machine learning model 545 may be trained by training data including reflection coefficients on a gamma chart. The training data may include input data and output data. According to example embodiments, the training data may include a set of input data and a set of output data. The set of input data may include a plurality of training reflection coefficients (e.g., on a gamma chart), and the set of output data may include a plurality of training events (e.g., values representing events (or probabilities of events). The plurality of training events may be the same as (or similar to) the plurality of events (e.g., at least one of a grip event, a head event, a free event, and/or a connection event). According to example embodiments, each respective training reflection coefficient in the set of input data is associated with a corresponding training event in the set of output data. The input data may be data inputted to the machine learning model 545, and the output data may be data outputted from the machine learning model 545 based on the input data. In example embodiments, the input data may include a reflection coefficient, and the output data may include a value representing an event (or a probability of an event). According to example embodiments, the machine learning model 545 may be trained by iteratively inputting each respective training reflection coefficient in the set of input data into the machine learning model 545, comparing an output generated by the machine learning model 545 to the corresponding training event in the set of output data associated with the respective training reflection coefficient, and adapting the machine learning model 545 according to a difference (e.g., an amount of difference) between the generated output and the corresponding training event (e.g., to minimize or reduce a loss function).

According to example embodiments of the present disclosure, the machine learning model 545 may learn a correlation(s) between various events and reflection coefficients. Through this, a relationship between a reflection coefficient and an event may be precisely analyzed even in a complex environment, and a reliable result may be provided in various wireless communication scenarios. In addition, by continuously training the machine learning model 545 through a real-time data feedback, a type of event may be added or the accuracy of identifying events may be improved.

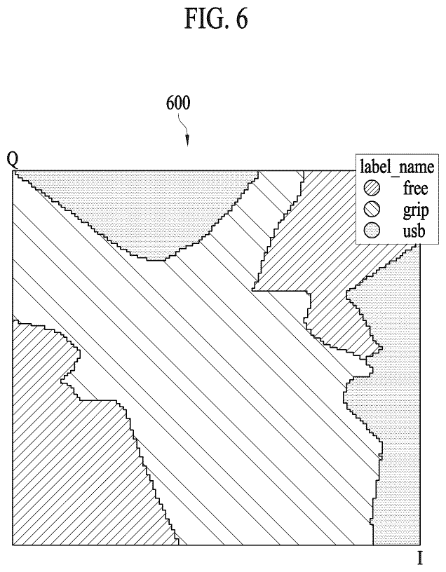

FIG. 6 is a diagram for illustrating a trained machine learning model according to example embodiments of the present disclosure. FIG. 6 shows a plot 600 as an example in which the machine learning model 545 (e.g., output generated by the machine learning model 545) of FIG. 5 is visualized and may represent a boundary and an area for each event corresponding to a reflection coefficient. Referring to FIG. 6, each area on the plot 600 may represent an event having the highest probability value with respect to a probability value outputted by the machine learning model 545, and an event corresponding to a reflection coefficient may be determined based on an area including the reflection coefficient.

In example embodiments, the machine learning model 545 may output a result value for a label such as a free event, a grip event, and/or a USB cable connection event according to an I component and a Q component of a reflection coefficient. For example, the result value of the machine learning model 545 may include a possibility (or probability) value for each of the free event, the grip event, and the USB cable connection event based on the inputted reflection coefficient. The first processor 130 may identify a label having a maximum (or highest) value among possibility (or probability) values as an event corresponding to the reflection coefficient. According to the present disclosure, as the machine learning model 545 may accurately set a boundary between events by learning a clustering relationship between reflection coefficients and events. Through this, for new data (in other words, a new reflection coefficient), an event to which the corresponding data belongs may be accurately predicted and sorted.

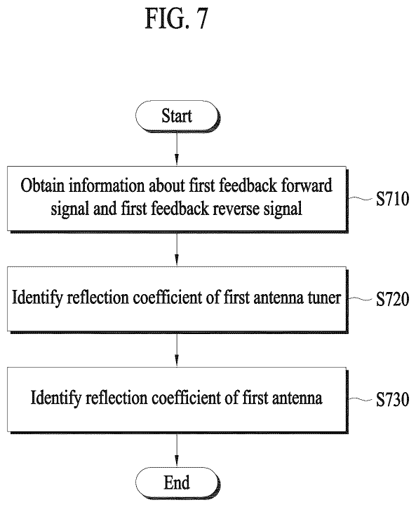

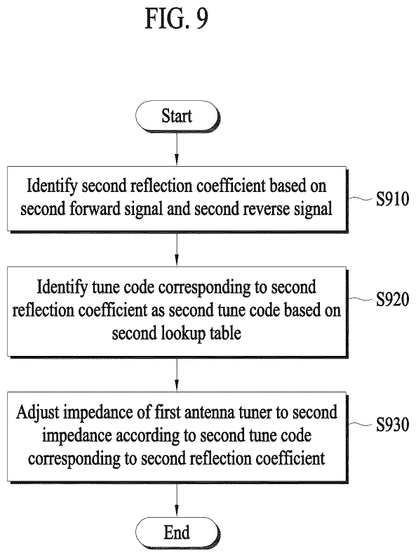

FIG. 7 is a flowchart for illustrating a method of controlling impedance of an antenna tuner according to example embodiments of the present disclosure. In example embodiments, the method of FIG. 7 may be performed by the first processor 130 of FIG. 1. Hereinafter, it is assumed that the first processor 130 of FIG. 1 controls the first antenna tuner 215-1 of FIG. 2. Referring to FIG. 7, a method of controlling impedance of the first antenna tuner 215-1 may include a plurality of operations S710 to S730. In example embodiments, operations S710 to S730 of FIG. 7 may be included in operation S310 of FIG. 3. In example embodiments, operations S710 to S730 of FIG. 7 may be included in operation S910 of FIG. 9 to be described below. In example embodiments, a first reflection coefficient may include at least one of the reflection coefficient Γᵢₙ of the first antenna tuner 215-1 and/or the reflection coefficient Γ_{L} of the first antenna 215-2.

In operation S710, information about a first feedback forward signal of a first forward signal and a first feedback reverse signal of a first reverse signal may be obtained. In example embodiments, the first processor 130 may obtain the information about the first feedback forward signal of the first forward signal and the first feedback reverse signal of the first reverse signal. For example, the coupler 213-1 of FIG. 2 may capture at least a portion of a forward signal as the first feedback forward signal through the first feedback port P3 and capture at least a portion of a reverse signal as the first feedback reverse signal through the second feedback port P4. The coupler 213-1 may provide the first feedback forward signal and the first feedback reverse signal to the feedback circuit 213-2, and the feedback circuit 213-2 may provide the information about the first feedback forward signal and the first feedback reverse signal to the first processor 130. In example embodiments, the information about the first feedback forward signal and the first feedback reverse signal may include an I component and a Q component of each of the first feedback forward signal and the first feedback reverse signal. In example embodiments, the information about the first feedback forward signal and the first feedback reverse signal may include an amplitude and a phase of each of the first feedback forward signal and the first feedback reverse signal.

In operation S720, the reflection coefficient Γᵢₙ of the first antenna tuner 215-1 may be identified. For example, a ratio of the first feedback forward signal and the first feedback reverse signal may be identified as the reflection coefficient Γᵢₙ of the first antenna tuner 215-1. In example embodiments, the first processor 130 may identify the ratio of the first feedback forward signal and the first feedback reverse signal as the reflection coefficient Γᵢₙ of the first antenna tuner 215-1. For example, the first processor 130 may identify a result value calculated using the following [Equation 1] as the reflection coefficient Γᵢₙ of the first antenna tuner 215-1.

$${Γ}_{i n} = \frac{b 4}{b 3} \qquad [ Equation 1 ]$$

As in [Equation 1], the reflection coefficient Γᵢₙ of the first antenna tuner 215-1 may be defined as a value obtained by dividing the second signal b4 of FIG. 2 by the first signal b3 of FIG. 2. Here, the first signal b3 may be the first feedback forward signal, and the second signal b4 may be the first feedback reverse signal. Each of the first signal b3 and the second signal b4 may be represented as a complex number including an I component and a Q component. An amplitude (or magnitude) of each of the first signal b3 and the second signal b4 may be calculated as a square root of a sum of squares of the I component and the Q component. A phase of each of the first signal b3 and the second signal b4 may be calculated by taking the arctangent of a value that is the Q component divided by the I component. The reflection coefficient Γᵢₙ of the first antenna tuner 215-1 may be represented as a complex number having information on a magnitude and a phase.

In operation S730, the reflection coefficient Γ_{L} of the first antenna 215-2 may be identified. For example, the reflection coefficient Γ_{L} of the first antenna 215-2 may be identified based on the reflection coefficient Fin of the first antenna tuner 215-1 and an S-parameter set. In example embodiments, the first processor 130 may identify the reflection coefficient Γ_{L} of the first antenna 215-2 based on the reflection coefficient Γᵢₙ of the first antenna tuner 215-1 and the S-parameter set. For example, the first processor 130 may identify a result value calculated using [Equation 2] as the reflection coefficient Γ_{L} of the first antenna 215-2.

$${Γ}_{L} = \frac{{Γ}_{i n} - {S}_{11}}{{Γ}_{i n} {S}_{22} - ( {S}_{11} {S}_{22} - {S}_{12} {S}_{21} )} \qquad [ Equation 2 ]$$

As in [Equation 2], the reflection coefficient Γ_{L} of the first antenna 215-2 may be defined by a relationship between the reflection coefficient Γᵢₙ of the first antenna tuner 215-1, which is calculated according to [Equation 1], a forward transmission parameter S₂₁, a reverse transmission parameter S₁₂, an input reflection parameter S₁₁, and an output reflection parameter S₂₂ included in the S-parameter set. The reflection coefficient Γᵢₙ of the first antenna tuner 215-1 may be represented as a complex number having information on a magnitude and a phase, and each parameter included in the S-parameter set may be represented as a complex number having information on a magnitude and a phase. However, [Equation 2] is merely an example, and the reflection coefficient Γ_{L} of the first antenna 215-2 may be calculated in another manner. In example embodiments, operation S730 may be omitted, and a reflection coefficient of a first antenna tuner identified in operation S720 may be used as the first reflection coefficient.

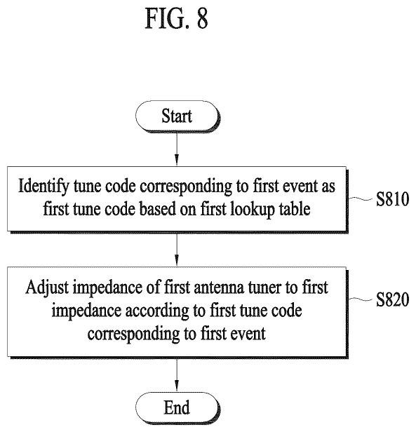

FIG. 8 is a flowchart for illustrating a method of controlling impedance of an antenna tuner according to example embodiments of the present disclosure. The method of FIG. 8 may be performed by the first processor 130 of FIG. 1. Hereinafter, it is assumed that the first processor 130 of FIG. 1 controls the first antenna tuner 215-1 of FIG. 2. Referring to FIG. 8, a method of controlling impedance of the first antenna tuner 215-1 may include a plurality of operations S810 and S820.

In operation S810, a tune code corresponding to a first event may be identified as a first tune code based on a first lookup table. In example embodiments, the first processor 130 may identify the tune code corresponding to the first event as the first tune code based on the first lookup table. The first lookup table may include a plurality of tune codes and a plurality of events that are mutually mapped. For example, events and tune codes of the first lookup table may be mapped one-to-one. If the first event is identified (e.g., based on the output of the machine learning model in operation S330), the first processor 130 may retrieve the first event from the first lookup table and identify a tune code mapped to the retrieved first event as the first tune code. In example embodiments, the first lookup table may be stored in a memory of the communication device 100, which is accessible by the first processor 130, or an internal memory of the first processor 130.

In operation S820, impedance of the first antenna tuner 215-1 (may also be referred to herein as a first impedance) may be adjusted to a first impedance (may also be referred to herein as a first impedance value) according to the first tune code corresponding to the first event. In example embodiments, the first processor 130 may adjust the impedance of the first antenna tuner 215-1 to the first impedance according to the first tune code identified in operation S810. For example, the first processor 130 may provide the first tune code corresponding to the first event to the first antenna tuner 215-1, and the first antenna tuner 215-1 may have the first impedance adjusted according to the first tune code. In example embodiments, the first impedance may be a unique (or defined) impedance corresponding to the first tune code, and a unique impedance may be preset (or alternatively, given or set) for each tune code. In example embodiments, the first processor 130 may adjust impedance of the second antenna tuner (may also be referred to herein as a second impedance) included in the second antenna module 125 of the second tuning network 120 to the first impedance according to the first tune code corresponding to the first event.

In example embodiments, operation S810 and operation S820 may be referred to as a coarse tuning operation. The coarse tuning operation may perform a tuning role of primarily (or initially) and rapidly adjusting impedance of an antenna tuner based on an event, and subsequently, the impedance may be more precisely adjusted through a fine tuning operation in some cases.

FIG. 9 is a flowchart for illustrating a method of controlling impedance of an antenna tuner according to example embodiments of the present disclosure. The method of FIG. 9 may be performed by the first processor 130 of FIG. 1. Hereinafter, it is assumed that the first processor 130 of FIG. 1 controls the first antenna tuner 215-1 of FIG. 2. Referring to FIG. 9, a method of controlling impedance of the first antenna tuner 215-1 may include a plurality of operations S910 to S930.

In operation S910, a second reflection coefficient may be identified based on a second forward signal and a second reverse signal. In example embodiments, the first processor 130 may identify the second reflection coefficient based on the second forward signal and the second reverse signal. The second forward signal may be a signal transmitted to the first antenna 215-2 through the first antenna tuner 215-1 while the impedance of the first antenna tuner 215-1 is at a first impedance value (e.g., contemporaneous with the impedance of the first antenna tuner 215-1 being adjusted to the first impedance value), and the second reverse signal may be a signal received through the first antenna tuner 215-1 as at least a portion of the second forward signal is reflected while the impedance of the first antenna tuner 215-1 is adjusted to the first impedance value (e.g., the impedance is at the first impedance value). In other words, the second forward signal and the second reverse signal may be a signal transmitted or received after a first forward signal and a first reverse signal. The first impedance may be an impedance adjusted according to a first tune code corresponding to a first event. The second reflection coefficient may be a reflection coefficient obtained after a first reflection coefficient. In example embodiments, the second reflection coefficient may include at least one of the reflection coefficient Γᵢₙ of the first antenna tuner 215-1 and/or the reflection coefficient Γ_{L} of the first antenna 215-2. The description with reference to FIG. 7 may be identically (or similarly) applied to the reflection coefficient Γᵢₙ of the first antenna tuner 215-1 and the reflection coefficient Γ_{L} of the first antenna 215-2.

In operation S920, a tune code corresponding to the second reflection coefficient may be identified as a second tune code based on a second lookup table. In example embodiments, the first processor 130 may identify the tune code corresponding to the second reflection coefficient as the second tune code based on the second lookup table. The second lookup table may include a plurality of tune codes and a plurality of reflection coefficients that are mutually mapped. For example, reflection coefficients and tune codes of the second lookup table may be mapped one-to-one. In example embodiments, if the second reflection coefficient is identified, the first processor 130 may retrieve the second reflection coefficient from the second lookup table and identify a tune code mapped to the retrieved second reflection coefficient as the second tune code. In example embodiments, the second lookup table may be stored in a memory of the communication device 100, which is accessible by the first processor 130, or an internal memory of the first processor 130.

In operation S930, impedance of the first antenna tuner 215-1 may be adjusted to a second impedance (may also be referred to herein as a second impedance value) according to the second tune code corresponding to the second reflection coefficient. In example embodiments, the first processor 130 may adjust the impedance of the first antenna tuner 215-1 to the second impedance according to the second tune code corresponding to the second reflection coefficient. For example, the first processor 130 may provide the second tune code corresponding to the second reflection coefficient to the first antenna tuner 215-1, and the first antenna tuner 215-1 may have the second impedance adjusted according to the second tune code. In example embodiments, the first processor 130 may adjust impedance of the second antenna tuner included in the second antenna module 125 of the second tuning network 120 to the second impedance according to the second tune code corresponding to the second reflection coefficient.

In example embodiments, operation S920 may be replaced by an operation of identifying the second tune code corresponding to the second reflection coefficient based on a gain of the first antenna tuner 215-1. In example embodiments, the first processor 130 may identify the second tune code corresponding to the second reflection coefficient based on the gain of the first antenna tuner 215-1.

Specifically, the first processor 130 may calculate a plurality of gains individually corresponding to a plurality of candidate S-parameter sets based on the reflection coefficient Γ_{L} of the first antenna 215-2 included in the second reflection coefficient. For example, the first processor 130 may calculate each gain (Gₜ) using the following [Equation 3].

$${G}_{t} = \frac{{\vert {S}_{21} \vert}^{2} ( 1 - {\vert {Γ}_{L} \vert}^{2} )}{{\vert 1 - {S}_{22} {Γ}_{L} \vert}^{2}} \qquad [ Equation 3 ]$$

Here, a gain Gₜ may be defined by a relationship between the reflection coefficient Γ_{L} of the first antenna 215-2, a forward transmission parameter S₂₁, and an output reflection parameter S₂₂ included in a candidate S-parameter set according to [Equation 3]. However, [Equation 3] is merely an example, and the gain Gₜ may be calculated in another manner.

The first processor 130 may select a candidate S-parameter set corresponding to a maximum (or highest) value among the plurality of gains as a new S-parameter set. The first processor 130 may identify a tune code mapped to the new S-parameter set as a new tune code. For example, the first processor 130 may identify a tune code corresponding to the candidate S-parameter set providing a gain of the maximum (or highest) value as the new tune code with reference to a third lookup table in which a plurality of tune codes and S-parameter sets mapped to each other.

In example embodiments, operations S910 to S930 may be referred to as a fine tuning operation. The fine tuning operation may perform a role of precisely adjusting impedance of an antenna tuner secondarily after a coarse tuning operation. According to the present disclosure, various events may be accurately sensed without a separate sensor such as a grip sensor, and based thereon, impedance of an antenna tuner may be precisely adjusted. According to the present disclosure, a sensor for sensing an event may be omitted, and thus, the design of the communication device 100 may be simplified and manufacturing costs may be reduced.

In a network (for example, the second tuning network 120) of the OL-AIT manner, precise impedance tuning may be difficult because no sensing circuit (or feedback loop) is present. According to the present disclosure, as described above with reference to the drawings, impedance matching may be performed even for the network of the OL-AIT manner by using a reflection coefficient measured through a sensing circuit of a network (for example, the first tuning network 110) of the CL-AIT manner. Accordingly, more precise and real-time impedance matching may also be performed in the OL-AIT manner.

According to example embodiments, while (or contemporaneous) with the impedance of the first antenna tuner 215-1 (and/or the second antenna tuner) being tuned to the first impedance in operation S820 (and/or tuned to the second impedance in operation S930), the communication device 100 may perform wireless communication with an external device. For example, the communication device 100 may generate a first signal (e.g., using the first processor 130), process the first signal to perform one or more among modulating, upconverting, filtering, amplifying and/or encrypting on the first signal (e.g., using the first transceiver 111 and/or the second transceiver 121), and transmit the processed first signal to the external device one or more antennas (e.g., using the first antenna module 115 and/or the second antenna module 125). Additionally or alternatively, the communication device 100 may receive a second signal from the external device via the one or more antennas (e.g., using the first antenna module 115 and/or the second antenna module 125), process the second signal to perform one or more among demodulating, downconverting, filtering, amplifying and/or decrypting on the second signal (e.g., using the first transceiver 111 and/or the second transceiver 121), and perform a further operation(s) based on the processed second signal. For example, the further operation(s) may include one or more of providing the processed second signal to a corresponding application executing on the communication device 100, storing the processed second signal in a memory of the communication device 100, sending a response signal to the external device (e.g., based on a processing result of the corresponding application executing on the communication device 100), etc.

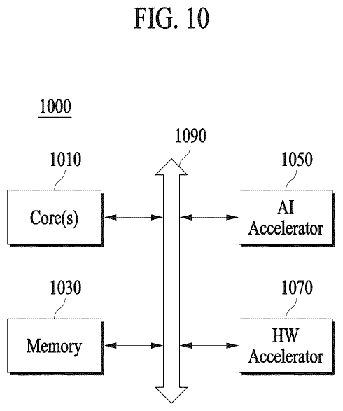

FIG. 10 is a block diagram illustrating an example of a device according to example embodiments of the present disclosure. In some example embodiments, a method of controlling impedance of an antenna tuner according to example embodiments of the present disclosure may be performed by a device 1000 illustrated in FIG. 10.

Referring to FIG. 10, in example embodiments, the device 1000 may include at least one core 1010, a memory 1030, an artificial intelligence (AI) accelerator 1050, and/or a hardware (HW) accelerator 1070. These components may communicate with each other through a bus 1090, and in example embodiments, may be integrated into a single semiconductor chip. In example embodiments, at least two components may be included in each different chip, and the corresponding semiconductor chips may be mounted on an identical (or similar) substrate.

The at least one core 1010 may execute instructions. For example, the at least one core 1010 may execute an operating system by executing instructions stored in the memory 1030 or execute application programs operating on the operating system. In example embodiments, the at least one core 1010 may assign a task to the AI accelerator 1050 and/or the HW accelerator 1070, and obtain a result of performing the task from the AI accelerator 1050 and/or the HW accelerator 1070. In example embodiments, the at least one core 1010 may be implemented as an application specific instruction set processor (ASIP) customized for a specific use and may support a dedicated instruction set.

The memory 1030 may have various structures for storing data. For example, the memory 1030 may include a volatile memory device such as dynamic random access memory (DRAM) and static random access memory (SRAM). The memory 1030 may include a non-volatile memory device such as flash memory and resistive random access memory (RRAM). The at least one core 1010, the AI accelerator 1050, and/or the HW accelerator 1070 may store data in the memory 1030 through the bus 1090 or read data from the memory 1030.

The AI accelerator 1050 may refer to hardware optimized (or configured) for AI applications. The AI accelerator 1050 may include a neural processing unit (NPU) implementing a neuromorphic structure. The AI accelerator 1050 may receive input data from the at least one core 1010 or the HW accelerator 1070 and process the input data and may generate output data and provide the output data to the at least one core 1010 or the HW accelerator 1070. In example embodiments, the AI accelerator 1050 may be programmable, and may be programmed by the at least one core 1010 or the HW accelerator 1070. The AI accelerator 1050 may be utilized for executing a machine learning model and optimizing (or improving) a trained model.

The HW accelerator 1070 may refer to hardware designed to perform specific data processing (for example, demodulation, modulation, encoding, and/or decoding) with higher speed. The HW accelerator 1070 may be programmable and may be controlled and programmed by the at least one core 1010 or the AI accelerator 1050.

The device 1000 may perform a method of controlling impedance of an antenna tuner according to example embodiments of the present disclosure and may be referred to as a device for controlling impedance of an antenna tuner. For example, the at least one core 1010 and/or the HW accelerator 1070 may perform an operation performed by the first processor 130 of FIG. 1, and the AI accelerator 1050 may perform an operation of executing a machine learning model, which is performed by the second processor 140 of FIG. 1.

The at least one core 1010 and/or the HW accelerator 1070 may generate and provide a first reflection coefficient to the AI accelerator 1050. The AI accelerator 1050 may execute a machine learning model in which a plurality of reflection coefficients and a plurality of events are learned. The AI accelerator 1050 may input the provided first reflection coefficient to the machine learning model and generate a first event (or information on the first event) corresponding to the first reflection coefficient as an output of the machine learning model to provide the first event (or the information thereon) to the at least one core 1010 and/or the HW accelerator 1070. The trained machine learning model executed by the AI accelerator 1050 may be updated based on data inputted when manufacturing the device 1000 or provided from outside while using the device 1000.

Conventional devices and methods for antenna tuner impedance adjustment rely on separate sensors (e.g., grip sensors) for detecting a grip of a user on a device. In response to detecting the grip, the impedance of the antenna tuner is adjusted to compensate for antenna degradation resulting from the grip. However, through this reliance on the grip sensor, the conventional devices and methods result in excessive manufacturing costs and device complexity.

However, according to example embodiments, improved devices and methods are provided for antenna tuner impedance adjustment. For example, the improved devices and methods may detect an event (e.g., a grip of a user on a device) based on a reflection coefficient of an antenna (e.g., using a trained machine learning model). Accordingly, the improved devices and methods are capable of accurately detecting the event and making a corresponding adjustment to the antenna tuner impedance without reliance on a separate sensor (e.g., a grip sensor). Therefore, the improved devices and methods overcome the deficiencies of the conventional devices and methods to at least reduce manufacturing costs and device complexity while improving communication performance.

According to example embodiments, operations described herein as being performed by the communication device 100, the first tuning network 110, the second tuning network 120, the first processor 130, the second processor 140, the first transceiver 111, the sensing circuit 113, the first antenna module 115, the second transceiver 121, the second antenna module 125, the first transceiver 211, the sensing circuit 213, the first antenna module 215, the coupler 213-1, the feedback circuit 213-2, the first antenna tuner 215-1, the second processor 540, the device 1000, the at least one core 1010, the AI accelerator 1050, and/or the HW accelerator 1070 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

In embodiments, the processing circuitry may perform some operations (e.g., the operations described herein as being performed by the machine learning model 545) by artificial intelligence and/or machine learning. As an example, the processing circuitry may implement an artificial neural network (e.g., the machine learning model 545) that is trained on a set of training data by, for example, a supervised, unsupervised, and/or reinforcement learning model, and wherein the processing circuitry may process a feature vector to provide output based upon the training. Such artificial neural networks may utilize a variety of artificial neural network organizational and processing models, such as convolutional neural networks (CNN), recurrent neural networks (RNN) optionally including long short-term memory (LSTM) units and/or gated recurrent units (GRU), stacking-based deep neural networks (S-DNN), state-space dynamic neural networks (S-SDNN), deconvolution networks, deep belief networks (DBN), and/or restricted Boltzmann machines (RBM). Alternatively or additionally, the processing circuitry may include other forms of artificial intelligence and/or machine learning, such as, for example, linear and/or logistic regression, statistical clustering, Bayesian classification, decision trees, dimensionality reduction such as principal component analysis, and expert systems; and/or combinations thereof, including ensembles such as random forests.

Herein, the machine learning model may have any structure that is trainable, e.g., with training data. For example, the machine learning model may include an artificial neural network, a decision tree, a support vector machine, a Bayesian network, a genetic algorithm, and/or the like. The machine learning model will now be described by mainly referring to an artificial neural network, but example embodiments are not limited thereto. Non-limiting examples of the artificial neural network may include a convolution neural network (CNN), a region based convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, a long short-term memory (LSTM) network, a classification network, and/or the like.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm, and/or functions, described in connection with example embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the memory 1030, the memory of the communication device 100, the memory of the first processor 130, etc.). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

As above, example embodiments are disclosed in the specification and drawings. While particular terms are used to describe example embodiments herein, the terms are merely used to describe the technical idea of the present disclosure and are not intended to limit meanings or limit the scope of the present disclosure specified in the claims. Therefore, a person of ordinary skill in the art may understand that various modifications and other equivalent examples may be made therefrom.

What is claimed is:

1. A communication device comprising:
a first tuning network including a first antenna and a first antenna tuner, the first antenna tuner being configured to adjust a first impedance according to a first received tune code;
a first processor configured to identify a first reflection coefficient based on a first forward signal and a first reverse signal, the first forward signal being transmitted to the first antenna through the first antenna tuner, and the first reverse signal being received through the first antenna tuner as at least a portion of the first forward signal is reflected; and
a second processor configured to execute a machine learning model, the machine learning model being trained based on a plurality of training reflection coefficients and a plurality of training events,
wherein the first processor is configured to,
provide the first reflection coefficient to the second processor, and
identify a first event corresponding to the first reflection coefficient based on an output of the machine learning model provided from the second processor.

2. The communication device of claim 1, wherein
the first event is among a plurality of events; and
the plurality of events include at least one of:
a grip event corresponding to a hand of a user being in contact with at least a first portion of the first antenna,
a head event corresponding to a head of the user being in contact with at least a second portion of the first antenna,
a free event corresponding to an absence of interference at the first antenna from an external object, or
a connection event corresponding to an external device being connected to the communication device through a cable.

3. The communication device of claim 1, further comprising:
a memory configured to store a first lookup table, the first lookup table mutually mapping a plurality of tune codes to a plurality of events, and the plurality of events including the first event,
wherein the first processor is configured to identify a first tune code corresponding to the first event from among the plurality of tune codes based on the first lookup table.

4. The communication device of claim 1, wherein the first processor is configured to:
cause the first antenna tuner to adjust the first impedance to a first impedance value by providing the first antenna tuner a first tune code, the first tune code corresponding to the first event; and
identify a second reflection coefficient based on a second forward signal and a second reverse signal,
wherein the second forward signal is transmitted to the first antenna through the first antenna tuner, and the second reverse signal is received through the first antenna tuner as at least a portion of the second forward signal is reflected, while the first impedance is adjusted to the first impedance value.

5. The communication device of claim 4, further comprising:
a memory configured to store a second lookup table, the second lookup table mutually mapping a plurality of tune codes to a plurality of reflection coefficients,
wherein the first processor is configured to identify a second tune code corresponding to the second reflection coefficient from among the plurality of tune codes based on the second lookup table.

6. The communication device of claim 4, wherein the first processor is configured to cause the first antenna tuner to adjust the first impedance to a second impedance value by providing the first antenna tuner a second tune code, the second tune code corresponding to the second reflection coefficient.

7. The communication device of claim 4, further comprising:
a second tuning network including a second antenna and a second antenna tuner, the second antenna tuner being configured to adjust a second impedance according to a second received tune code,
wherein the first processor is configured to cause the second antenna tuner to adjust the second impedance a second impedance value by providing the second antenna tuner a second tune code, the second tune code corresponding to the second reflection coefficient.

8. The communication device of claim 4, wherein at least one of the first reflection coefficient or the second reflection coefficient includes a reflection coefficient of the first antenna tuner or a reflection coefficient of the first antenna.

9. The communication device of claim 8, wherein the first processor is configured to calculate the reflection coefficient of the first antenna based on the reflection coefficient of the first antenna tuner and a scattering parameter (S-parameter) set.

10. The communication device of claim 1, wherein the first tuning network includes a coupler connected to the first antenna tuner, the coupler being configured to capture a first feedback forward signal of the first forward signal and a first feedback reverse signal of the first reverse signal.

11. A method of controlling impedance of at least one antenna tuner, the method comprising:
identifying a first reflection coefficient based on a first forward signal and a first reverse signal, the first forward signal being transmitted to a first antenna through a first antenna tuner, and the first reverse signal being received through the first antenna tuner as at least a portion of the first forward signal is reflected;
providing the first reflection coefficient to a machine learning model trained based on a plurality of training reflection coefficients and a plurality of training events; and
identifying a first event corresponding to the first reflection coefficient based on an output of the machine learning model.

12. The method of claim 11, wherein
the first event is among a plurality of events; and
the plurality of events include at least one of:
a grip event corresponding to a hand of a user being in contact with at least a first portion of the first antenna,
a head event corresponding to a head of the user being in contact with at least a second portion of the first antenna,
a free event corresponding to an absence of interference at the first antenna from an external object, or
a connection event corresponding to an external device being connected to a communication device through a cable.

13. The method of claim 11, further comprising:
adjusting a first impedance of the first antenna tuner to a first impedance value according to a first tune code, the first tune code corresponding to the first event.

14. The method of claim 13, further comprising:
identifying the first tune code as one corresponding to the first event among a plurality of tune codes based on a first lookup table, the first lookup table mutually mapping the plurality of tune codes to a plurality of events.

15. The method of claim 13, further comprising:
identifying a second reflection coefficient based on a second forward signal and a second reverse signal, wherein the second forward signal is transmitted to the first antenna through the first antenna tuner, and the second reverse signal is received through the first antenna tuner as at least a portion of the second forward signal is reflected, while the first impedance is adjusted to the first impedance value; and
adjusting the first impedance of the first antenna tuner to a second impedance value according to a second tune code, the second tune code corresponding to the second reflection coefficient.

16. The method of claim 15, further comprising:
identifying the second tune code corresponding to the second reflection coefficient based on a second lookup table, the second lookup table mutually mapping a plurality of tune codes and a plurality of reflection coefficients.

17. The method of claim 11, wherein the first reflection coefficient includes at least one of a reflection coefficient of the first antenna tuner or a reflection coefficient of the first antenna.

18. The method of claim 17, wherein the identifying the first reflection coefficient comprises:
obtaining information about a first feedback forward signal of the first forward signal and a first feedback reverse signal of the first reverse signal; and
identifying a ratio of the first feedback forward signal and the first feedback reverse signal as the reflection coefficient of the first antenna tuner.

19. The method of claim 18, wherein the identifying the first reflection coefficient comprises identifying the reflection coefficient of the first antenna based on the reflection coefficient of the first antenna tuner and a scattering parameter (S-parameter) set.

20. A device configured to control an impedance of at least one antenna tuner, the device comprising:
processing circuitry configured to,
identify a reflection coefficient based on a forward signal and a reverse signal, the forward signal being transmitted to a first antenna through a first antenna tuner, and the reverse signal received through the first antenna tuner as at least a portion of the forward signal is reflected,
provide the reflection coefficient to a machine learning model trained based on a plurality of training reflection coefficients and a plurality of training events, and
identify an event corresponding to the reflection coefficient based on an output of the machine learning model.
